(19) United States
(12) Patent Application Publication
(10) Pub. No.: US 2008/0282983 A1
(43) Pub. Date: Nov. 20, 2008

(54) High Temperature Vacuum Evaporation Apparatus

(76) Inventor: Walter David Braddock, IV, Rochester, MN (US)

Correspondence Address: NEIFELD IP LAW, PC, 4813-B EISENHOWER AVENUE, ALEXANDRIA, VA, 22304, US

(21) Appl. No.: 10/581,316

(22) PCT Filed: Dec. 8, 2004
(86) PCT No.: PCT/US04/38235

§ 371 Date: Jun. 2, 2006

Related U.S. Application Data
(60) Provisional application No. 60/527,760, filed on Dec. 9, 2003.

(51) Int. Cl. C23C 16/00

(52) U.S. Cl. 118/726; 427/120

(57) ABSTRACT

A filament, heat shield, supporting base comprised of SiC with ceramic insulators and top plate that together form an effusion assembly for use in the vacuum evaporation, molecular beam epitaxy, and ultra high vacuum deposition of epitaxial materials. The effusion assembly used together with a crucible and source material allow for the vacuum evaporation of species above 1250° C. when quantities of reactive gaseous species such as oxygen, sulphur, or reactive nitrogen are present in the deposition chamber. The relative chemical inertness of SiC even at elevated temperatures allows the SiC filament assembly to be used at high temperature especially in the presence of oxygen for the high purity epitaxial nucleation and growth layered electronic materials including semiconductors, metals, oxides, dielectric multilayer stacks, sulfides and oxides.

### RELATED APPLICATIONS

This application claims the benefit of U.S. provisional patent application 60/527,760 filed on Dec. 9, 2003, the disclosure of which is incorporated by reference.

### FIELD OF THE INVENTION

The present invention generally relates to an effusion cell for vacuum evaporation for use in an ultra high vacuum (UHV) environment including; molecular beam ultra high vacuum deposition, ultra high vacuum chemical vapor deposition, high vacuum sputtering where the thermal evaporation and deposition of materials is conducted in an environment that contains a partial pressure of a reactive species such as oxygen, nitrogen, or sulphur, or reactive versions or combinations of these species with or without the presence of plasma.

### BACKGROUND OF THE INVENTION

In the general field of semiconductor manufacturing vacuum evaporation, UHV Deposition, Atomic Layer Deposition, and Molecular Beam Epitaxy are widely used for the formation of epitaxial structures that include semiconductor structures or devices with gate insulators or semiconductor structures or devices with passivation layers consisting of epitaxial dielectrics. In very simplified terms UHV Deposition or the MBE process relies on co-evaporation of many materials simultaneously using thermally induced vacuum evaporation, directed beams of gasses, and/or beams of plasmas, and sputtered beams of compounds to form crystalline or amorphous epitaxial oxides, semiconductors, insulators, and multilayer structures of these materials. The epitaxial layer of these materials are often comprised of 2, 3, or 4 or more elements and metal, semiconductor, and insulator layers may also include dopant materials that affect the electrical properties of the epitaxial layers, or cause certain materials to become dominant. For the proper deposition of certain semiconductors, (such as Al or containing compound semiconductors) an oxygen free vacuum environment is necessary to achieve high purity semiconductor thin films that are uncontaminated. However, in the deposition of epitaxial oxides or epitaxial dielectric thin films oxygen, sulphur, and reactive nitrogen must be used to assist in the formation of deposited refractory or rare earth metal oxide layers that when combined form more complex dielectrics multilayer structures formed on a semiconductor structure or substrate. Often, reactive oxygen must be utilized either in atomic form, excited molecules, or as a pulsed or continuous flow directed gas, or plasma beam. By directing multiple materials gasses toward a substrate in an accurate and selective fashion, well-defined layers of various compositions or stoichiometry are formed in an epitaxial manner on a substrates. These well-defined layers then serve as the combined semiconductor+dielectric structure for the fabrication of semiconductor devices including silicon MOSFETs, compound semiconductor MOSFETs or and CMOS structures using any number of semiconductors including Si, strained Si, Ge, GaN, GaAs, ZnSe or other compound semiconductors that utilize alternative gate dielectrics. In addition these dielectric layers for compound semiconductor MOSFETs and CMOS may be used as semiconductor lasers epitaxial facet dielectric passivation layers, heterojunction bipolar transistors passivation layers especially between the base and emitter junction, and optical detector materials with integral antireflection layers and passivation layers. The thickness of these layers is controlled by the evaporation or effusion rate of incident materials, the substrate temperature that can control re-evaporation from the substrate, and the deposition time of each layer. In semiconductor manufacturing, the processes of forming these layers may be accomplished using computer control and automation or by manually controlling the deposition process resulting in well-defined single layer or multi-layered structures. Those skilled in the art of epitaxial growth of semiconductors will recognize, a critical factor in the fabrication of any semiconductor device on a substrate is the depth and composition of the dopant profile of the layered structure, atomically smooth interface between adjacent layers, and abrupt planar interfaces between semiconductor materials and epitaxially deposited dielectrics and insulators. Typically, it is preferred that the deposition of any particular layer be uniform throughout and across a particular wafer in a semiconductor epitaxial structure, however intentional gradients or composition changes in such semiconductor structures is also often desirable. UHV deposition techniques including MBE, UHV-CVD, and atomic layer deposition (ALD) appear capable of producing layered structures with well-defined and abrupt interfaces. In addition, the epitaxial deposition of alternative gate dielectrics for silicon that are not necessarily comprised of Si-oxides, and other epitaxial dielectrics that find use for the passivation of compound semiconductors, or formation of compound semiconductor MOSFETs or compound semiconductor CMOS is enabled by the vacuum evaporation apparatus that is the subject of this invention.

It is in furtherance of the goal of forming crystalline, polycrystalline, nanocrystalline, or amorphous epitaxial dielectric layers (including oxides, nitrides, sulphides and combinations thereof forming gate insulator structures or high-K gate dielectric stacks) on crystalline or amorphous substrates with low interface state defect densities, low contamination levels, precise composition, and controlled electrical properties that is one object of the present effusion cell assembly invention. It is the goal of the present invention to prevent the contamination when very high temperature vacuum evaporation must be used in combination with reactive gaseous species, hot filament, and heated heat shielding that can facilitate contamination or unwanted doping of the epitaxial layers. It is further a goal of the present invention to allow the thermal vacuum evaporation of very high temperature materials such as refractory metals and or rare-earth oxides or suboxides in the presence of substantial partial pressures of oxide, nitride, or sulphide molecules, or in the presence of active or reactive species of oxygen, nitrogen, or sulphur without degradation of the effusion cell or contamination of the epitaxial layer. It is known by those skilled in the art that temperatures in the range of 1200-2400° C. may be required for the sufficient thermal evaporation of refractory metals such as, for example; Hf, Sc, Sm, Nb, Ta, W, Mo, Gd, Lu, and other rare earth elements and their oxides that are often used in the formation of multilayer high dielectric constant layers for use as passivation layers or gate dielectrics for both silicon and compound semiconductors. It is a further goal of this invention to allow for the vacuum evaporation of molecular species including the vacuum evaporation and MBE of metal oxide, metal nitride, or metal sulphide materials that may be combined and directed toward a heated substrate to allow formation of various epitaxial layers. In the past, effusion cell filaments have been constructed mainly of materials such as Ta, Mo, W, and Graphite that readily react with oxygen, sulphur, and active nitrogen that can limit the maximum operating temperature of vacuum evaporation, and cause uncontrolled doping or unwanted contamination of the epitaxial layers.

Conventional filaments for use in MBE effusion cell assemblies often require complex arrangements using ribbon, wire, or stampings of Ta, Re, W, or Mo wire, arranged and supported on an insulating support system typically fabricated from pyrolytic boron nitride For example, one assembly involves winding or weaving a tantalum wire through a plurality of perforated PBN discs in a cylindrical or conical and serpentine manner.

Another such assembly involves coiling a tungsten, tantalum, or Mo wire about a insulating ceramic tube. A third assembly utilizes a plurality of self-supporting tungsten helical filaments. Although other assemblies are known, five known drawbacks are common to all such assemblies. First, refractory metal filaments in general and specifically tantalum filaments have a low emissivity as compared to SiC and thus required very high operating temperatures to supply heat to a combined crucible and source material assembly. In the case of Ta, the filament temperature is considerably higher than the crucible and source material temperature, and these extended temperatures can limit the reliability and lifetime of the effusion cell assembly especially when operated at high temperatures. Second, assemblies utilizing refractory metal filament are inherently expensive due to their complexity. Third, the assembly labor for refractory metal filament assemblies is tedious complicated, and expensive. Fourth, the high temperature of the Ta, W, or Mo filament materials cause rapid reaction and degradation in the presence of reactive species such as oxygen, active nitrogen, and sulphur, and this thermally induced degradation causes unwanted transport of Ta, W, and Mo into the resulting epitaxial materials during growth. Fifth, if these refractory metal filaments come in contact with molten source material, especially liquid metals these materials immediately react in a manner that destroys the effusion cell or causes irreversible changes and usually catastrophic failure to the effusion cell. Even without catastrophic failure, effusion cell filaments constructed of these materials are often subject to premature failure and poor reliability when operated in oxygen or reactive environment at high temperature.

As stated, one of the most critical components of a UHV Deposition System or MBE system is the effusion cell assembly. In general, an effusion cell is the source of the thermally evaporated atomic or molecular beam. Usually, a material is placed in the effusion cell assembly, which is effectively a crucible formed of a refractory material, and heated to a temperature at which a beam of atoms or molecules are thermally excited and emitted area as well as the purity thereof impinging upon the substrate directly determines the composition growth rate for each molecular or atomic layer of the structure as well as the electrical characteristics thereof.

Although conceptually an MBE system appears straightforward, in actual practice the subtleties of contamination and unintentional doping or contamination of epitaxial deposited materials drives any best practices in the art. For example, the materials used in the construction of the effusion cell assembly are critical because the cell is required to operate at rather high temperatures (between 1200-2400° C.) and under an ultra high vacuum (usually below pressures of 10-9 Torr). Consequently, the materials chosen must be as free of impurities as possible, must not react with any active species present in the vacuum depsition chamber, and neither out-gas or decompose at elevated temperature, either of which would severely contaminate the beam flux impinging on the semiconductor substrate.

The primary element of the effusion cell assembly is, of course, the filament and inner heat shield that work together to provide heat and a means of thermal localization that heats the crucible and the material contained therein.

### BRIEF DESCRIPTION OF THE DRAWING

FIG. 1 is a perspective view that shows SiC filament (20) (consisting of an inner SiC material and an outer SiC encapsulating layer), cylindrical SiC heat shield (10) generally disposed around filament (20), and one of a plurality of insulators (30) that keep heat shield (10) from electrically shorting filament (20).

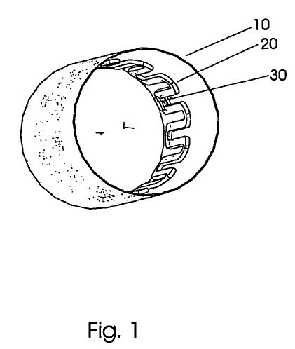

FIG. 2 is a perspective view that shows a SiC filament (60) in combination with SiC heat shield (50), a plurality of insulators (70), and bottom base plate (90) that supports the bottom of the SiC filament in one embodiment of the invention.

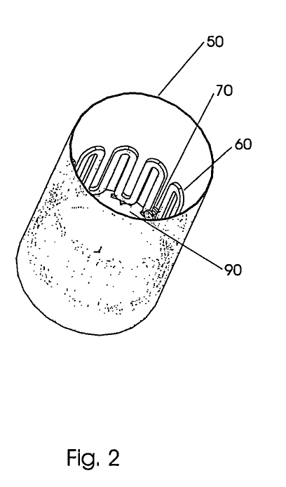

FIG. 3 is a perspective view that shows a cylindrically serpentine SiC filament (100) in combination with SiC heat shield (110), base plate (120), and a top plate (130) with an orifice to allow effusion from the crucible. The top plate assists in the retention of a larger fraction of heat inside the effusion cell assembly than that shown in the embodiment of FIG. 2.

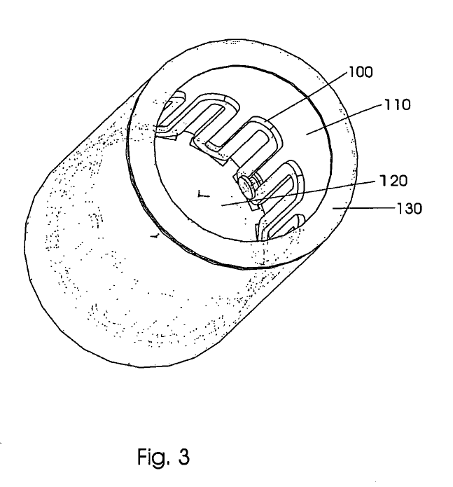

FIG. 4 is a perspective view that shows the generally cylindrical serpentine SiC filament (140) with insulators (150), heat shields, base plate, or top plate.

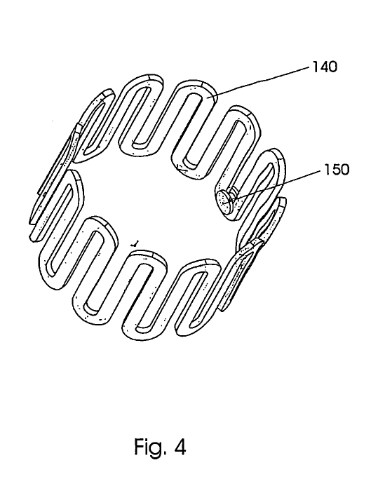

### SUMMARY OF THE INVENTION

In one preferred embodiment, the effusion cell filament assembly utilizes a generally cylindrically serpentine SiC filament that has both a very high emissivity for optimum thermal emission and coupling to the crucible and source material, and also excellent resistance to oxygen exposure. This SiC filament is comprised of an inner SiC core that may consist of a more porous and conductive grade of SiC that potentially is contains dopants to assist in the conductivity of the inner SiC filament material, and an outer dense and non-porous SiC layer meant to seal or separate the inner SiC core from the UHV environment. This outer dense, preferably non-porous SiC layer is typically deposited using a CVD technique.

In a second preferred embodiment, the effusion cell filament assembly utilizes a generally conically serpentine SiC filament that has both a very high emissivity for optimum thermal emission and coupling to the crucible and source material, and also excellent resistance to oxygen exposure. This second SiC filament is comprised of an inner SiC core that may consist of a more porous and conductive grade of SiC that contains dopants to assist in the conductivity of the filament, and an outer dense and non-porous SiC layer meant to seal or separate the inner SiC core from the UHV environment. This outer dense, preferably non-porous SiC layer is typically deposited using a CVD technique or physical vapor transport technique.

In a third embodiment of the invention a generally cylindrical SiC heat shield is utilized to surround the filament, capture and direct heat during operation, and form a highly emissive black-body type of thermal cavity capable of more uniformly heating source material and the crucible. The heat shield cylinder is also most preferentially comprised of SiC, but may be comprised of any ceramic or non-metallic material that provide some degree of thermal insulation.

In a fourth embodiment a SiC base-plate provides support to the generally cylindrical heat shield, filament and insulators that together form a filament assembly. This base plate in combination with the cylindrical SiC heat shield forms a more effective thermal cavity capable of trapping heat in the manner similar to a black-body radiation cavity.

In the fifth embodiment, a top plate comprised of any number of ceramics or refractory metals used by those skilled in the art including, SiC, Graphite, Mo, Re, Ta, W, Ir, C, Al203, BN, PBN, etc. is used to further capture and focus heat on the crucible and source material, and further improve the black body characteristics of the effusion source for vacuum evaporation. The most preferable version of this top plate consists of a two-piece assembly comprising an inner SiC plate and an outer refractory metal shield with a small space maintained between the inner SiC plate and outer refractory metal shield by a small diameter piece of refractory metal wire.

In a sixth embodiment, the filament assembly contains a crucible with one closed end and one generally open end, and this crucible contains source material that may be comprised of any solid or liquid element of the periodic table or any solid or liquid compound formed therefrom.

In a seventh preferred embodiment the filament assembly contains a temperature sensing device including a thermocouple, resistance temperature device, or access for optical pyrometer in order to provide a means of measuring the temperature of the crucible, source material, or internal volume of the cavity formed by the filament assembly, heat shield, based plate, top plate, and any combination thereof.

In an eighth preferred embodiment two or more sets of filaments, heat shield, insulator are combined to form a multi filament effusion cell for vacuum evaporation utilizing SiC filaments of the structure described previously. Together these multiple filaments may be used in concert to place a temperature gradient onto the crucible and source material contained in the effusion cell used for high temperature vacuum evaporation.

In a ninth preferred embodiment, the ends of the SiC filament are coated with a conformal coating of a refractory metal such as W, Mo, or Ta that forms a silicide with silicon and assists in providing a low resistance ohmic contact between refractory metal connectors or clamps and said SiC filament. The electrical contact region of the filament typically utilizes many layers of Ta, Nb, W or Mo foil wrapped many times around the ends of the SiC filament in the same manner as tape or foil is wrapped on a roll. This multi-layer roll structure of refractory metal assists in easing the thermal stress between the current supplying leads and SiC filament, and also distributes any point loads present on the SiC more uniformly across the local surface of the SiC filament used to make electrical connection.

In a tenth preferred embodiment, the filament is comprised of an inner SiC filament and an outer ceramic layer of boron nitride, pyrolytic boron nitride, aluminum nitride, or other nitride based ceramic.

These and other objects are provided by a method of using, a method of making, and an effusion cell designed for use in vacuum evaporation, comprising: a self supporting high emissivity heater filament comprising SiC, said filament extending in a serpentine path; a heat shield that partially encloses said heater filament; a plurality of insulators separating surfaces of said heater filament from surfaces of said heat shield; a supporting baseplate supporting said heat shield and said filament; and a crucible disposed radially inward of said heater filament and designed to retain material.

2. The effusion cell of claim 1 wherein said heater filament is constructed out of silicon carbide that is comprised of an inner porous materials and an outer non-porous SiC material of high density.

This invention utilizes the refractory nature of silicon carbide, its high emissivity at elevated temperatures, and its controlled and low reactivity with oxygen, nitrogen, and sulphur at high temperature in order to provide a new class of effusion cell with a more reliable and useful filament apparatus that is more reliable at high temperature and less contaminating of epitaxial layers grown using UHV deposition techniques. It is another object of the present invention to provide an effusion cell assembly that remains relatively cool externally while it provides efficient and uniform radiant heat transfer to the source material in the crucible. This object is accomplished, at least in part, by an effusion cell assembly: a high emissivity SiC filament, SiC heat shielding and the SiC base plate and generally cylindrical SiC heat shield as described in this document.

Preferably, the SiC filament has a serpentine electrical path which is in the form of a cylinder. Such a serpentine path is preferable in order to provide the filament with a practical ohmic resistance, reduce stray electromagnetic fields, and to uniformly distribute the radiation or heat about and through the crucible and within the cavity formed by the combination of the filament, cylindrical heat shield, SiC base plate, and top plate if present. In operation, the temperature of the filament may reach on the order of with an operating amperage of about 20-25 amps using a practical voltage that is as high as possible but usually below approximately DC.

Although the present assembly has been described with respect to a series of specific embodiment, it will be understood that other arrangements and configurations may also be developed and represented in the practice of this invention. Therefore, the scope of the present invention is deemed limited only by the following claims and the reasonable interpretation of the same.

What is claimed is:

1. An effusion cell designed for use in vacuum evaporation, comprising: a self supporting high emissivity heater filament comprising SiC, said filament extending in a serpentine path; a heat shield that partially encloses said heater filament; a plurality of insulators separating surfaces of said heater filament from surfaces of said heat shield; a supporting baseplate supporting said heat shield and said filament; and a crucible disposed radially inward of said heater filament and designed to retain material.

2. The effusion cell of claim 1 wherein said heater filament is constructed out of silicon carbide that is comprised of an inner porous materials and an outer non-porous SiC material of high density.

3. The effusion cell of claim 2 wherein said SiC filament is encapsulated in a CVD deposited outer layer of densified SiC with low porosity.

4. The effusion cell of claim 1 wherein said heater filament is constructed from of silicon carbide encapsulated in a ceramic layer comprising such and BN, PBN, diamond, refractory metal oxides.

5. The effusion cell of claim 1 wherein said heater filament is constructed from of SiC encapsulated in a insulating ceramic such and BN, PBN, diamond, or refractory metal oxides.

6. The effusion cell of claim 1 where the cylindrical heat shield is comprised of silicon carbide, PBN, or combinations thereof.

7. The effusion cell of claim 1 where the supporting baseplate comprises silicon carbide, PBN or combinations thereof.

8. The effusion cell of claim 1 wherein said cylindrical heat shield is comprised of an inner ceramic layer and an outer metallic layer.

9. The effusion cell of claim 1 wherein said filament providing a substantially uniform radiation therefrom when electrical current passes therethrough.

10. The effusion cell of claim 1 wherein said heat shield is generally cylindrical.

11. The effusion cell of claim 1 wherein said heat shield is generally conical.

12. The effusion cell of claim 1 wherein said heat shield is generally partially spherical.

13. The effusion cell of claim 1 wherein said heat shield is generally annular 14. The effusion cell of claim 1 wherein said filament extends along a generally cylindrical contour.

15. The effusion cell of claim 1 wherein said heat shield comprises a ceramic material.

16. A vacuum deposition system including the effusion cell of claim 1.

17. A method of making an effusion cell designed for use in vacuum evaporation, comprising: providing a self supporting high emissivity heater filament comprising SiC, said filament extending in a serpentine path; providing a heat shield that partially encloses said heater filament; providing a plurality of insulators separating surfaces of said heater filament from surfaces of said heat shield; providing a supporting baseplate supporting said heat shield and said filament; and providing a crucible disposed radially inward of said heater filament and designed to retain material.

18. A method of using an effusion cell, said effusion cell comprising: a self supporting high emissivity heater filament comprising SiC, said filament extending in a serpentine path; a heat shield that partially encloses said heater filament; a plurality of insulators separating surfaces of said heater filament from surfaces of said heat shield; a supporting baseplate supporting said heat shield and said filament; and a crucible disposed radially inward of said heater filament and designed to retain material; and said method comprising heating said heater filament.
